(19) United States
(12) Patent Application Publication
(10) Pub. No.: US 2006/0160267 A1
(43) Pub. Date: Jul. 20, 2006

(54) Under bump metallurgy in integrated circuits

(75) Inventors: Hyeong Ryeol Hur, Singapore (SG); Yew Kay Yuen, Singapore (SG); See Chian Lim, Singapore (SG); Puay Gek Chua, Singapore (SG); Kah Wee Gan, Singapore (SG); Jae-Yong Song, Singapore (SG); Yonggang Jin, Singapore (SG); Kyaw Oo Aung, Singapore (SG)

Correspondence Address: THE LAW OFFICES OF MIKIO ISHIMARU, 333 W. EL CAMINO REAL, SUITE 330, SUNNYVALE, CA, 94087, US

(73) Assignee: STATS ChipPAC Ltd., Singapore (SG)

(21) Appl. No.: 11/035,637

(22) Filed: Jan. 14, 2005

(51) Int. Cl. H01L 21/50; H01L 21/48; H01L 21/44

(52) U.S. Cl. 438/106

(57) ABSTRACT

An integrated circuit package and method of manufacture is provided. A substrate having a number of contact pads exposed through a passivation layer thereon has a first under bump metallurgy layer over at least one of the contact pads. A top under bump metallurgy layer of copper having a thickness of less than about 800 angstroms is formed over the first under bump metallurgy layer.

### TECHNICAL FIELD

The present invention relates generally to semiconductors, and more particularly to a method and apparatus for packaging flip chip semiconductors.

### BACKGROUND ART

With continuously decreasing semiconductor device dimensions and increasing device-packaging densities, the packaging of semiconductor devices has continued to gain in importance. In the electronics industry, the continuing goal has been to reduce the size of electronic devices such as in digital cameras and camcorders.

In the past, integrated circuits, or chips, were packaged in leadframe packages using wire bonds using metal wires, but the packaging technology has been moving towards ball bond packages using solder balls, or bumps, which allow for a higher density of connections. The process of using solder bumps is often referred to as flip chip mounting, or bonding.

In flip-chip bonding technology, one of the most important processes is to form solder bumps on the bonding pads of the chip. The material used for the bonding pads of the chip is usually aluminum or copper. However, the solder used to form the solder bumps tends to react with the aluminum or copper. To solve this problem, under-bump metallurgy (UBM) pads are formed on the bonding pads before the solder bumps are formed to minimize reaction between the solder in the solder bumps and the aluminum or copper in the bonding pads. The UBM has to be well bonded to the solder bumps and the bonding pads, and functions as a diffusion barrier layer to prevent the solder bumps from reacting with the bonding pads.

The conventional method for manufacturing the UBM includes defining by a photolithography process an area over the bonding pads, which is covered by the UBM. There are many known processes for forming bumps for flip-chip mounting. Solder bumping consists of placing the UBM over the bond pads by sputtering, plating, or a similar means. The process of forming the UBM removes the passivation, or oxide, layer on the bond pad and defines a solder-wettable area. Solder is then deposited over the UBM by a suitable method, e.g., evaporation, electroplating, screen-printing, needle depositing, or other suitable process.

Various types of UBM are in use. A UBM, such as a nickel-vanadium/copper (NiV/Cu) UBM, is used to form the UBM for the printed bumping process. Other types of UBM are titanium-tungsten/nickel-vanadium (TiW/NiV) and chromium/chromium-copper/copper (Cr/CrCu/Cu).

Tin (Sn) solder is typically used for the balls because it has a high surface tension for forming small balls. Sn solder bonds well to pads of copper (Cu), which is a very good solder wettable material. Lead-free solders have become popular to avoid the use of lead in the manufacturing process. One such solder is a eutectic alloy of Sn, silver (Ag), and copper (Cu).

Despite improvements in UBM formation problems still exist in flip chip mounting solder bumps exhibit voids that adversely affect the fatigue life of the solder bump connections thereby reducing the reliability of semiconductor packages. Additionally, every UBM design tends to react differently with the solder used to form the bumps resulting in a lack of consistent performance of the flip chip mounted integrated circuits.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package and method of manufacture. A substrate having a number of contact pads exposed through a passivation layer thereon has a first under bump metallurgy layer over at least one of the contact pads, and a top under bump metallurgy layer of copper having a thickness of less than about 800 angstroms is formed over the first under bump metallurgy layer. Preferably, the top under bump metallurgy layer has a thickness from about 250 to 500 angstroms.

Voids in solder bumps and in solder balls over a UBM are reduced thereby improving the reliability of semiconductor packages.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a view of an integrated circuit package in accordance with one embodiment of the present invention;

FIG. 2 is a close-up view of a portion of one of the structure in FIG. 1 in an intermediate stage of manufacture;

FIG. 3 is the structure of FIG. 2 after deposition of first and second under bump metallurgy layers;

FIG. 4 is the structure of FIG. 3 after deposition and patterning of a photoresist;

FIG. 5 is the structure of FIG. 4 after removal of the photoresist;

FIG. 6 is the structure of FIG. 5 after formation of a solder bump;

FIG. 7 is a close-up view of a portion of one of the structure in FIG. 1 in an intermediate stage of manufacture in accordance with another embodiment of the present invention;

FIG. 8 is the structure of FIG. 7 after deposition of first and second under bump metallurgy layers;

FIG. 9 is the structure of FIG. 8 after deposition and patterning of a photoresist;

FIG. 10 is the structure of FIG. 9 after removal of the photoresist;

FIG. 11 is the structure of FIG. 10 after formation of a solder bump; and

FIG. 12 is a flow chart of a method for manufacturing an integrated circuit package in accordance with an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail.

Likewise, the drawings showing embodiments of the apparatus/device are semi-diagrammatic and not to scale and, particularly, some of the dimensions are for the clarity of presentation and are shown greatly exaggerated in the FIGs. Generally, the device can be operated in any orientation. In addition, where multiple embodiments are disclosed and described having some features in common, for clarity and ease of illustration and description thereof like features one to another will ordinarily be described with the same reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

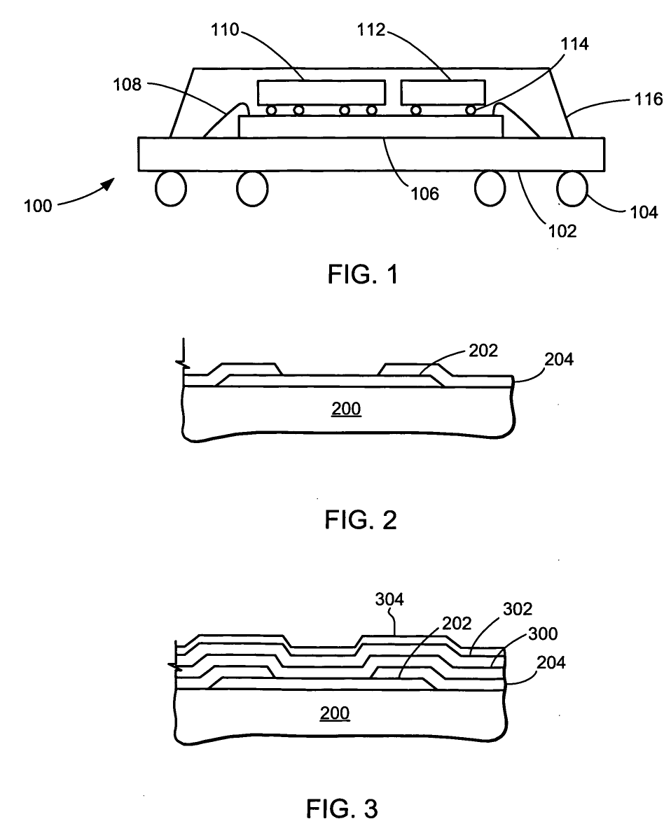

Referring now to FIG. 1, therein is shown an integrated circuit package 100 manufactured in accordance with an embodiment of the present invention. The integrated circuit package 100 has a package substrate 102 with a number of solder balls 104 on the bottom, and a bottom semiconductor die 106 on the top of the package substrate 102.

The bottom semiconductor die 106 is wire bonded by a number of wire bonds 108 to the package substrate 102. On top of the bottom semiconductor die 106 are a first top semiconductor die 110 and a second top semiconductor die 112 that are ball bonded to the bottom semiconductor die 106 by a number of solder bumps 114.

The bottom semiconductor die 106, the first top semiconductor die 110 and the second top semiconductor die 112 are encapsulated by an encapsulant 116 of a material such as epoxy or plastic. Each of the dies has a semiconductor material substrate. The dies may be connected in different combinations by different combinations of wire, solder bumps, and solder balls within the integrated circuit package 100.

Referring now to FIG. 2, therein is shown a close-up view of a top or bottom surface of semiconductor die or package substrate in an intermediate stage of manufacture. The semiconductor die could be the bottom semiconductor die 106, the first top semiconductor die 110, the second top semiconductor die 112, or the package substrate 102.

In one embodiment, the top of the bottom semiconductor die 106 includes a portion generically described as a substrate 200. The substrate 200 has a number of Input/Output (I/O) contact pads represented by a contact pad 202 exposed through a passivation layer 204 thereon.

The contact pad 202 generally is formed of a wire-bond pad material such as aluminum (Al), or an alloy of aluminum such as aluminum/copper (AlCu). The passivation layer 204 is of a dielectric material such as silicon oxide (SiO₂).

Referring now to FIG. 3, therein is shown the structure of FIG. 2 after deposition of a first under bump metallurgy (UBM) layer 300 and a second UBM layer 302.

The first UBM layer 300 is of a material that is formed over the contact pad 202 and the passivation layer 204. The material of the first UBM layer 300 can vary depending upon the particular UBM design being used. The first UBM layer 300 is selected to bond well with the contact pad 202 and the passivation layer 204.

For example, in a TiW/NiV UBM, the first UBM layer 300 is a TiW alloy. The second UBM layer 302 is of a material that bonds well to the first UBM layer 300 and provides a solder wettable material layer. For example, the second UBM layer 302 can be NiV depending on the particular UBM being used. NiV provides a good soldering wettable material for the number of solder bumps 114 and the number of solder balls 104 shown in FIG. 1.

It has been discovered that forming a top UBM layer 304 that is a very thin layer of Cu of less than about 800 angstroms as the top UBM layer significantly reduces the occurrence of voids in the number of solder bumps 114 and the number of solder balls 104 shown in FIG. 1. Preferably, the top UBM layer 304 is from about 250 to about 500 angstroms thick. The thickness of the top UBM layer 304 can vary depending upon the feature size of the UBM.

For example, in a UBM that has a material other than Cu as the second UBM layer 302, such as the TiW/NiV UBM, an additional very thin layer of Cu is formed as the top UBM layer 304 of the UBM. The use of the very thin layer of Cu as the top UBM layer 304 significantly reduces the occurrence of voids in the number of solder bumps 114 and the number of solder balls 104 shown in FIG. 1.

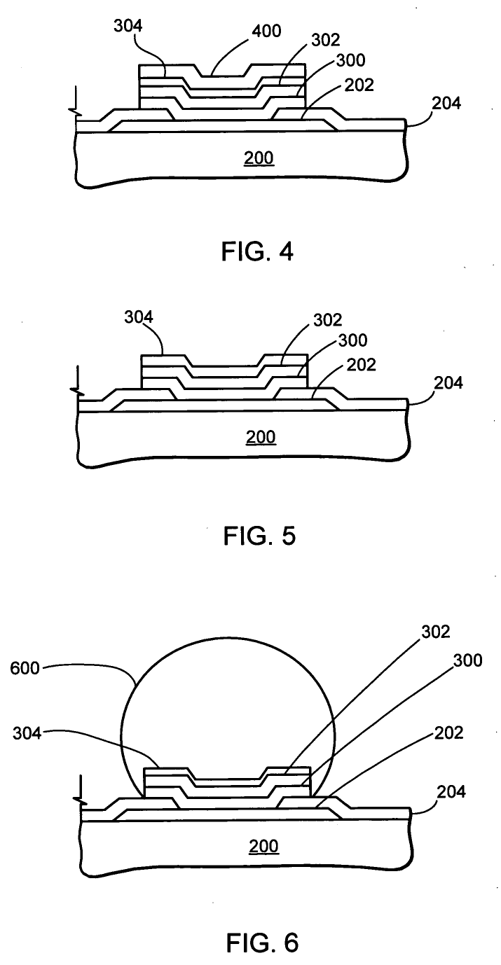

Referring now to FIG. 4, therein is shown the structure of FIG. 3 after deposition and patterning of a photoresist 400. The photoresist 400 is patterned followed by processing or etching removal of the first UBM layer 300, the second UBM layer 302, and the top UBM layer 304 from all areas except over the contact pad 202 and a portion of the passivation layer 204.

Referring now to FIG. 5, therein is shown the structure of FIG. 4 after removal of the photoresist 400 from the top UMB layer 304. The UBM including the first UBM layer 300, the second UBM layer 302, and the top UBM layer 304 is thus formed over the contact pad 202.

Referring now to FIG. 6, therein is shown the structure of FIG. 5 after a solder bump 600 has been formed over the top UBM layer 304. The solder bump 600 is representative of the number of solder bumps 114 and the number of solder balls 104 shown in FIG. 1. Preferably, the solder used is solder material of at least one of a eutectic, high lead, lead free, tin, silver, copper, an alloy thereof, and a combination thereof.

Solder is formed over the top UBM layer 304 by a suitable method, such as evaporation, electroplating, screen-printing, needle depositing, or other suitable process. Preferably, screen-printing of the solder is used. The solder is then reflowed by applying heat to form the solder bump 600. Electrical contact is made between the solder bump 600 and the contact pad 202 through the top UBM layer 304, the second UBM layer 302, and the first UBM layer 300.

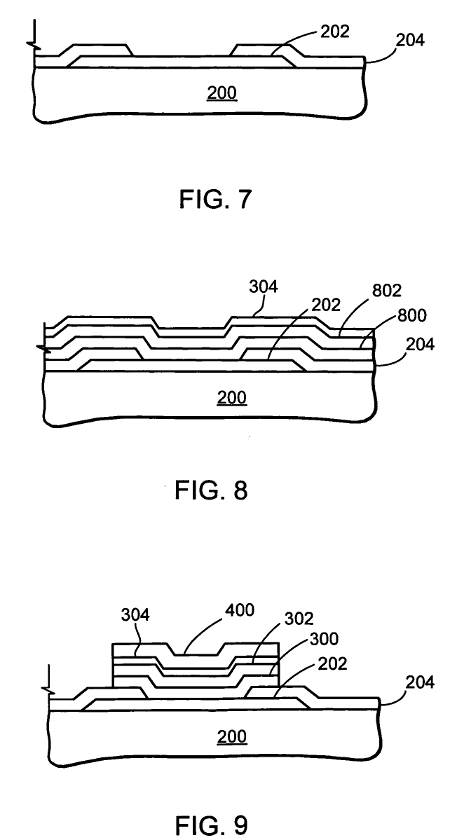

Referring now to FIG. 7, therein is shown a close-up view of a top or bottom surface of semiconductor die or package substrate in an intermediate stage of manufacture in accordance with another embodiment of the present invention. The semiconductor die could be the bottom semiconductor die 106, the first top semiconductor die 110, the second top semiconductor die 112, or the package substrate 102 shown in FIG. 1.

The top of the bottom semiconductor die 106 includes a portion generically described as the substrate 200. The substrate 200 has a number of Input/Output (I/O) contact pads represented by the contact pad 202 exposed through the passivation layer 204 thereon.

The contact pad 202 generally is formed of a wire-bond pad material such as aluminum (Al), or an alloy of aluminum such as aluminum/copper (AlCu). The passivation layer 204 is of a dielectric material such as silicon oxide (SiO₂).

Referring now to FIG. 8, therein is shown the structure of FIG. 7 after deposition of a first under bump metallurgy (UBM) layer 800 and a second UBM layer 802.

The first UBM layer 800 is of a material that is formed over the contact pad 202 and the passivation layer 204. The material of the first UBM layer 800 can vary depending upon the particular UBM design being used. The first UBM layer 800 is selected to bond well with the contact pad 202 and the passivation layer 204.

For example, in a Cr/CrCu/Cu UBM, the first UBM layer 800 is Cr. The second UBM layer 802 is of a material that bonds well to the first UBM layer 800. For example, in the Cr/CrCu/Cu UBM the second UBM layer 802 is a CrCu alloy. The Cr/CrCu/Cu UBM also has a top UBM layer 304 formed over the second UBM layer 802. The top UBM layer 304 provides a good soldering wettable material for the number of solder bumps 114 and the number of solder balls 104 shown in FIG. 1.

It has been discovered that forming the top UBM layer 304 that is a very thin layer of Cu having a thickness of less than about 800 angstroms significantly reduces the occurrence of voids in the number of solder bumps 114 and the number of solder balls 104 shown in FIG. 1.

Referring now to FIG. 9, therein is shown the structure of FIG. 8 after deposition and patterning of the photoresist 400. The photoresist 400 is patterned followed by processing or etching removal of the first UBM layer 800, the second UBM layer 802, and the top UBM layer 304 from all areas except over the contact pad 202 and a portion of the passivation layer 204.

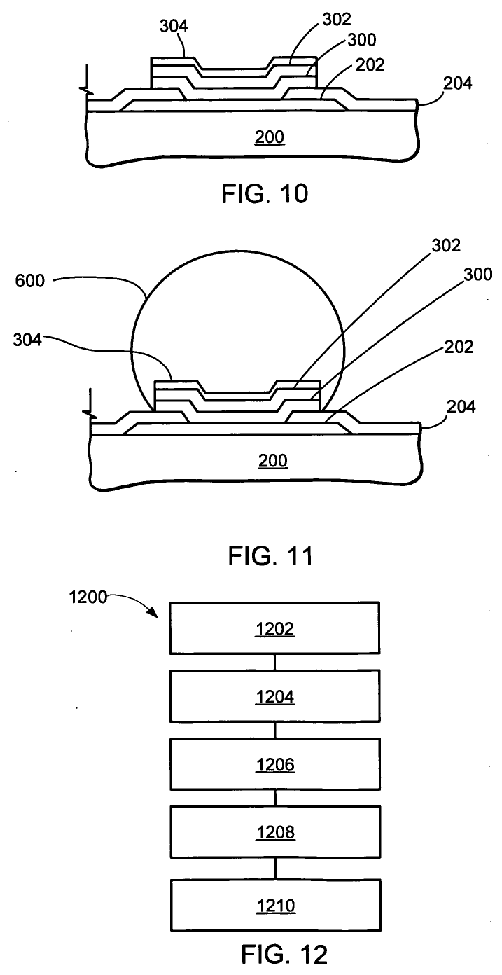

Referring now to FIG. 10, therein is shown the structure of FIG. 9 after removal of the photoresist 400 from the top UMB layer 304. The UBM including the first UBM layer 800, the second UBM layer 802, and the top UBM layer 304 thus is formed over the contact pad 202.

Referring now to FIG. 11, therein is shown the structure of FIG. 10 after the solder bump 600 has been formed over the top UBM layer 304. The solder bump 600 is representative of the number of solder bumps 114 and the number of solder balls 104 shown in FIG. 1. Preferably, the solder used is solder material of at least one of a eutectic, high lead, lead free, tin, silver, copper, an alloy thereof, and a combination thereof.

Solder is formed over the top UBM layer 304 by a suitable method, e.g., evaporation, electroplating, screen-printing, needle depositing, or other suitable process. The solder is then reflowed by applying heat to form the solder bump 600. Electrical contact is made between the solder bump 600 and the contact pad 202 through the top UBM layer 304, the second UBM layer 802, and the first UBM layer 800.

Referring now to FIG. 12, therein is shown a method 1200 for manufacturing an integrated circuit package in accordance with the present invention. The method 1200 includes: providing a substrate having a number of contact pads exposed through a passivation layer thereon in a block 1202; forming a first under bump metallurgy layer over the substrate in a block 1204; forming a top under bump metallurgy layer of copper having a thickness of less than about 800 angstroms over the first metallurgy layer in a block 1206; removing the top metallurgy layer while leaving a portion thereof over at least one of the contact pads in a block 1208; and removing the first metallurgy layer while leaving a portion thereof over the portion of the at least one of the contact pads in a block 1210.

The present invention has been found to be useful with a variety of UBM structures. If used with UBM structures, such as the TiW/NiV UBM described above with reference to FIGS. 2-6, a very thin layer of Cu having a thickness of less than about 800 angstroms is formed over the NiV layer of the UBM. If used with UBM structures that have a Cu layer as the upper UBM layer, such as the Cr/CrCu/Cu UBM described above with reference to FIGS. 7-11, the Cu layer is formed to have a thickness of less than about 800 angstroms. It has been discovered that providing a top UBM layer of Cu having a thickness of less than about 800 angstroms reduces the occurrence of voids in solder bumps and solder balls in both types of UBM structures.

Thus, it has been discovered that the method and apparatus of the present invention furnish important and heretofore unavailable solutions, capabilities, and functional advantages for integrated circuit packages. The resulting process and configurations are straightforward, economical, uncomplicated, highly versatile, and effective, use conventional technologies, and are thus readily suited for manufacturing semiconductor devices that are fully compatible with conventional manufacturing processes and technologies.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

The invention claimed is:

1. A method for manufacturing an integrated circuit package comprising:
providing a substrate having a number of contact pads exposed through a passivation layer thereon;
forming a first under bump metallurgy layer over the substrate;
forming a top under bump metallurgy layer of copper having a thickness of less than about 800 angstroms over the first metallurgy layer;
removing the top under bump metallurgy layer while leaving a portion thereof over at least one of the contact pads; and
removing the first under bump metallurgy layer while leaving a portion thereof over the portion of the at least one of the contact pads.

2. The method as claimed in claim 1 wherein:
forming a top under bump metallurgy layer of copper forms a top under bump metallurgy layer having a thickness from about 250 to about 500 angstroms.

3. The method as claimed in claim 1 further comprising:
forming a second under bump metallurgy layer between the first under bump metallurgy layer and the top under bump metallurgy layer, wherein:
forming the first under bump metallurgy layer uses at least one of chromium, an alloy thereof, and a compound thereof; and
forming a second under bump metallurgy layer uses at least one of chromium, copper, an alloy thereof, and a compound thereof.

4. The method as claimed in claim 1 further comprising:
forming a solder bump over the top under bump metallurgy layer;
connecting the substrate to at least one of a semiconductor die, package substrate and combinations thereof; and
encapsulating the substrate.

5. The method as claimed in claim 4 wherein:
forming a solder bump uses a solder of at least one of a eutectic, high lead, lead free, tin, silver, copper, an alloy thereof, and a combination thereof.

6. A method for manufacturing an integrated circuit package comprising:
providing a substrate having a number of contact pads exposed through a passivation layer thereon;
forming a first under bump metallurgy layer on the number of contact pads;
forming a top under bump metallurgy layer of copper having a thickness of less than about 800 angstroms over the first under bump metallurgy layer;
removing the top under bump metallurgy layer while leaving a portion thereof over at least one of the number of contact pads;
removing the first under bump metallurgy layer while leaving a portion thereof over the at least one of the contact pads;
forming a solder bump over the top under bump metallurgy layer;
connecting the substrate to at least one additional substrate; and
encapsulating the substrate.

7. The method as claimed in claim 6 wherein:
forming a top under bump metallurgy layer of copper forms a top under bump metallurgy layer having a thickness from about 250 to about 500 angstroms.

8. The method as claimed in claim 6, wherein:
providing the substrate provides the first contact pad using at least one of aluminum, an alloy thereof, or a compound thereof; and
forming the first under bump metallurgy layer uses at least one of titanium, tungsten, an alloy thereof, and a compound thereof.

9. The method as claimed in claim 6 wherein:
forming a solder bump uses a solder of at least one of a eutectic, high lead, lead free, tin, silver, copper, an alloy thereof, and a combination thereof.

10. The method as claimed in claim 6 further comprising:
forming a second under bump metallurgy layer between the first under bump metallurgy layer and the top under bump metallurgy layer, wherein:
forming the first under bump metallurgy layer uses at least one of chromium, an alloy thereof, and a compound thereof; and
forming a second under bump metallurgy layer uses at least one of chromium, copper, an alloy thereof, and a compound thereof.

11. An integrated circuit package comprising:
a substrate having a number of contact pads exposed through a passivation layer thereon;
a first under bump metallurgy layer over at least one of the contact pads and;
a top under bump metallurgy layer of copper having a thickness of less than about 800 angstroms over the first under bump metallurgy layer.

12. The integrated circuit package as claimed in claim 11 wherein:
the top under bump metallurgy layer of copper has a thickness from about 250 to about 500 angstroms.

13. The integrated circuit package as claimed in claim 11 further comprising:
a solder ball over the top under bump metallurgy layer;
wherein the substrate is connected to at least one of a semiconductor die, package substrate and combinations thereof; and
an encapsulant encapsulating the substrate.

14. The integrated circuit package as claimed in claim 13 wherein:
the solder ball comprises a solder of at least one of a eutectic, high lead, lead free, tin, silver, copper, an alloy thereof, and a combination thereof.

15. The integrated circuit package as claimed in claim 11 further comprising:
a second under bump metallurgy layer between the first under bump metallurgy layer and the top under bump metallurgy layer, wherein:
the first under bump metallurgy layer comprises at least one of chromium, an alloy thereof, and a compound thereof; and
the second under bump metallurgy layer comprises at least one of chromium, copper, an alloy thereof, and a compound thereof.

16. An integrated circuit package comprising:
a substrate having a number of contact pads exposed through a passivation layer thereon;
a first under bump metallurgy layer on the number of contact pads;
a top under bump metallurgy layer of copper having a thickness of less than about 800 angstroms over the first under bump metallurgy layer;
a solder bump over the top under bump metallurgy layer;
wherein the substrate is connected to at least one additional substrate; and
an encapsulant encapsulating the substrate.

17. The integrated circuit package as claimed in claim 16 wherein:
the top under bump metallurgy layer of copper has a thickness from about 250 to about 500 angstroms.

18. The integrated circuit package as claimed in claim 16 wherein:
the substrate comprises a the first contact pad using at least one of aluminum, an alloy thereof, or a compound thereof; and
the first under bump metallurgy layer comprises at least one of titanium, tungsten, an alloy thereof, and a compound thereof.

19. The integrated circuit package as claimed in claim 16 wherein:
the solder bump comprises a solder of at least one of a eutectic, high lead, lead free, tin, silver, copper, an alloy thereof, and a combination thereof.

20. The integrated circuit package as claimed in claim 16 further comprising:
a second under bump metallurgy layer between the first under bump metallurgy layer and the top under bump metallurgy layer, wherein:
the first under bump metallurgy layer comprises at least one of chromium, an alloy thereof, and a compound thereof; and
the second under bump metallurgy layer comprises at least one of chromium, copper, an alloy thereof, and a compound thereof.
